(19) United States
(12) Patent Application Publication
(10) Pub. No.: US 2013/0264194 A1
(43) Pub. Date: Oct. 10, 2013

(54) METHOD FOR MANUFACTURING CARBON FILM AND PLASMA CVD METHOD

(71) Applicant: CANNON ANELVA CORPORATION, Kawasaki-shi (JP)

(72) Inventors: Ge XU, Kawasaki-shi (JP); Kazuto YAMANAKA, Kawasaki-shi (JP); Tsutomu HIROISHI, Kawasaki-shi (JP); Shogo HIRAMATSU, Kawasaki-shi (JP)

(21) Appl. No.: 13/911,152

(22) Filed: Jun. 6, 2013

Related U.S. Application Data
(63) Continuation of application No. PCT/JP2011/007037, filed on Dec. 16, 2011.

(30) Foreign Application Priority Data
Dec. 28, 2010 (JP) 2010-294007

(51) Int. Cl. C23C 16/513

(52) U.S. Cl. CPC C23C 16/513
USPC 204/192.38

(57) ABSTRACT

The present invention provides a method of manufacturing a carbon film and a plasma CVD method capable of performing film formation while controlling the temperature of a substrate as well as film properties. A process chamber according to one embodiment of the present invention includes a holder configured to hold a substrate, magnetic-field producing means configured to produce magnetic fields inside the process chamber, shields configured to suppress film deposition on the magnetic-field producing means, heat dissipating sheets configured to suppress heating of the magnetic-field producing means, and moving means configured to move the magnetic-field producing means. The magnetic-field producing means is characterized in being moved in such a direction as to increase or decrease the volume of a space between the magnetic-field producing means and the holder.

### CROSS-REFERENCES TO RELATED APPLICATIONS

This application is a continuation application of International Application No. PCT/JP2011/007037, filed Dec. 16, 2011, which claims the benefit of Japanese Patent Application No. 2010-294007, filed Dec. 28, 2010. The contents of the aforementioned applications are incorporated herein by reference in their entireties.

### TECHNICAL FIELD

The present invention relates to a method for manufacturing a carbon film and a plasma CVD (Chemical Vapor Deposition) method.

### BACKGROUND ART

In plasma CVD, a thin film is formed on a surface of a substrate to be processed (a process target) by bringing a source gas for film formation to a plasma state by discharge in vacuum and decomposing the source gas by the energy of the plasma. In another method often employed, the quality of a film is improved by forming the film with ionized molecules accelerated by negative potential applied to the process target.

Particularly in film formation of carbon-based thin films such as DLC (Diamond-Like Carbon) films, an apparatus configuration and a method for forming a film on both of surfaces of a substrate to be processed are employed (see Patent Document 1).

In Patent Document 1, magnets are arranged inside a chamber in such a way that the magnets may produce magnetic fields near a substrate in parallel to a surface of the substrate. Thereby, plasma density near the substrate is raised to improve the speed of forming the DLC thin-films.

### CITATION LIST

### Patent Document

Patent Document 1: Japanese Patent Application Laid-Open No. 2010-31374

### SUMMARY OF INVENTION

In recent years, carbon films used for fuel cells are also formed using such plasma CVD as described above. Required properties of the carbon films used for fuel cells include conductivity and durability.

If conductive carbon films are to be formed, they need to be formed with the substrate having a high temperature. To be more specific, a step of increasing the temperature of the substrate is required before or at an initial stage of the film formation, and a step of forming the films while maintaining the high temperature of the substrate is required, as well. In other words, to improve the conductivity, a plasma CVD process requires temperature control of the substrate.

However, in a plasma CVD method using a conventional plasma CVD apparatus, controlling film properties (e.g., film stress) other than the conductivity automatically determines conditions for the substrate, such as the value of voltage applied and the pressure of gas in a chamber. For this reason, those conditions restrict the amount of current flowing from the plasma to the substrate, to make it difficult to control the substrate temperature by changing the amount of current or power. In other words, it has been conventionally difficult to control the conductivity of carbon films and control the properties of the carbon films other than the conductivity at the same time.

The present invention has been made in view of the above problem, and provides a method of manufacturing a carbon film and a plasma CVD method, capable of forming a carbon film on a substrate to be processed, while obtaining the conductivity of the film through temperature control of the substrate and also controlling properties of the film other than the conductivity.

A first aspect of the present invention is a CVD method for performing a film forming process on a substrate by using a film forming apparatus including a vacuum vessel and magnetic-field producing means for generating a magnetic field inside the vacuum vessel, and is characterized in that the method comprises the steps of: producing a plasma in a space between the magnetic-field producing means and the substrate inside the vacuum vessel; and while the substrate is being processed, moving the magnetic-field producing means in such a direction as to increase or decrease a volume of the space between the magnetic-field producing means and the substrate.

A second aspect of the present invention is a CVD method for performing a film forming process on a substrate by using a film forming apparatus including a vacuum vessel and magnetic-field producing means for generating a magnetic field inside the vacuum vessel, and is characterized in that the method comprises the steps of: moving the magnetic-field producing means so that a distance between the magnetic-field producing means and the substrate reaches a first distance; producing a plasma of an inert gas in a space between the magnetic-field producing means and the substrate inside the vacuum vessel; heating the substrate by the plasma of the inert gas; moving the magnetic-field producing means so that the distance between the magnetic-field producing means and the substrate reaches a second distance which is larger than the first distance; producing a plasma of a source gas in the space between the magnetic-field producing means and the substrate inside the vacuum vessel; and forming a film on the substrate by the plasma of the source gas.

By using the method according to the present invention, a carbon film can be deposited on a substrate to be processed while controlling the temperature of the substrate and at the same time controlling the properties of the film.

### BRIEF DESCRIPTION OF DRAWINGS

FIG. 1 is a top view of the internal structure of a vacuum processing apparatus according to one embodiment of the present invention.

FIG. 2 is a front view of the internal structure of the vacuum processing apparatus according to the one embodiment of the present invention.

FIG. 3 is a side view of the internal structure of the vacuum processing apparatus according to the one embodiment of the present invention.

FIG. 4A is a front view of a holder according to one embodiment of the present invention.

FIG. 4B is a sectional view taken along A-A′ in FIG. 4A.

FIG. 5 is a schematic diagram of a process chamber according to one embodiment of the present invention.

FIG. 6A is a front view of a holder according to one embodiment of the present invention.

FIG. 6B is a sectional view taken along A-A′ in FIG. 6A.

FIG. 7A is a front view of a holder according to one embodiment of the present invention.

FIG. 7B is a sectional view taken along A-A′ in FIG. 7A.

FIG. 8 is a schematic diagram of magnetic-fieid producing means according to one embodiment of the present invention.

FIG. 9 ia a schematic diagram of magnetic-field producing means according to one embodiment of the present invention.

FIG. 10 is a schematic diagram of magnetic-field producing means according to one embodiment of the present invention.

### DESCRIPTION OF EMBODIMENTS

An embodiment of the present invention is described below with reference to the drawings. However, the present invention is not limited to this embodiment. Note that, in the drawings described below, parts having the same functions are denoted by the same reference numerals, and may not be described repeatedly.

### Embodiment

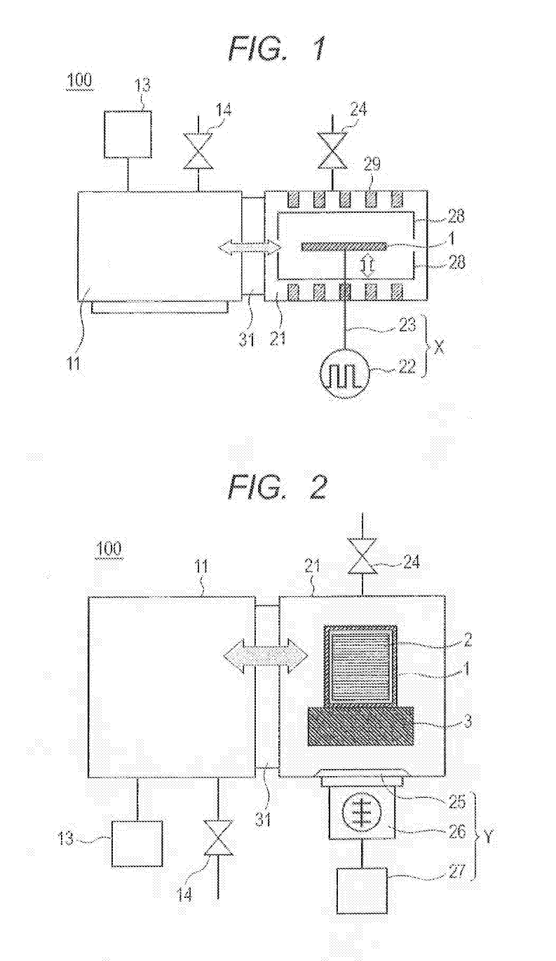

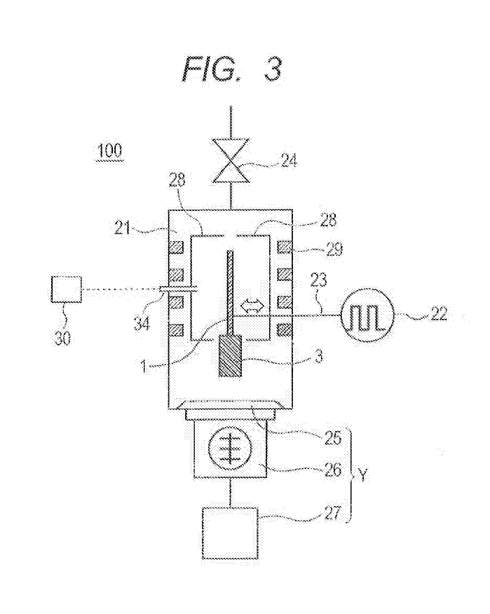

FIG. 1 is a schematic diagram of the internal structure of a vacuum processing apparatus 100 seen from above. FIG. 2 is a schematic diagram of the internal structure of the vacuum processing apparatus 100 seen from front. FIG. 3 is a schematic diagram of the internal structure of the vacuum processing apparatus 100 seen from side.

The vacuum processing apparatus 100 according to this embodiment has a load lock chamber 11 and a process chamber 21 which are evacuated. The load lock chamber 11 and the process chamber 21 are structured such that they can be spatially separated by a gate valve 31. In the vacuum processing apparatus 100, a substrate 2 is placed into the load lock chamber 11 exposed to the atmosphere, and the load lock chamber 11 is then evacuated. Thereafter, the gate valve 31 located between the evacuated load lock chamber 11 and the vacuum-storing process chamber 21 is opened, and the substrate is transported to the process chamber 21 by a slider 3. In the process chamber 21, the transported substrate 2 is subjected to a predetermined process.

Such a configuration of the apparatus is advantageous in that the process chamber 21 does not need to be exposed to the atmosphere every time a new substrate is to be placed. Although the vacuum processing apparatus 100 according to this embodiment is configured by including one load lock chamber 11 and one process chamber 21, it may be configured by including multiple process chambers, depending on the process steps to be performed. Also, another load lock chamber may be provided on the opposite side of the process chamber 21 from the load lock chamber 11, so that the substrate transported from the load lock chamber 11 may be transported to the other load lock chamber after being processed in the process chamber 21.

The load lock chamber 11 has an exhaust portion 13 and a vent portion 14 for the exposure to the atmosphere. For example, a dry pump is used as the exhaust portion 13, and a gas introduction portion configured to introduce a N₂ (nitrogen) gas or dry air is used as the vent portion 14.

The process chamber 21 is a vacuum vessel in which the substrate 2 is subiected to a process such as heating, cooling, film formation, or etching. The process chamber 21 has a gas introduction portion 24 configured to introduce a discharge gas and an exhaust part Y. For example, the exhaust part Y has a turbo-molecular pump 26 and a back-pressure exhaust pump 27. Desirably, the exhaust part Y further has a main valve 25 or a variable orifice capable of changing the exhaust conductance. The process chamber 21 further includes a port 34 which causes the inside of the process chamber 21 to communicate with the outside of the vacuum processing apparatus 100, and temperature measuring means 30 for measuring the temperature of the substrate 2 through the port 34. The temperature measuring means 30 is not limited to such a form, and can be selected from various means. One capable of performing measurement without coming into contact with the substrate 2 is particularly desirable in view of substrate processing reproducibility and the like. For example, a radiation thermometer is preferably used.

The process chamber 21 further has a voltage application part X. The voltage application part X is configured to apply a negative high voltage to the substrate 2 via a holder 1, and includes a power supply 22 and a voltage application cylinder 23. The voltage application cylinder 23 operates the voltage application part X so that the voltage application part X may not be connected to the holder 1 while the holder 1 is being transported and that the voltage application part X may be connected to the holder 1 during the plasma processing.

In the process chamber 21, shields 28 are provided surrounding the holder 1 to prevent or suppress film deposition onto an inner wall of the process chamber 21 while the substrate is processed. Magnetic-field producing means 29 is provided on the opposite side of each shield 28 from the holder 1 or the substrate 2 held by the holder 1. In this embodiment, in order to perform plasma processing on both of surfaces of the substrate 2, the magnetic-field producing means 29 is provided both on the opposite side of one of the shields 28 from one surface of the substrate 2 and on the opposite side of the other one of the shields 28 from the other surface of the substrate 2. To perform plasma processing evenly on the substrate 2, the substrate 2 and the magnetic-field producing means 29 are desirably arranged such that the surface of the substrate 2 is in parallel with a magnet-holding surface of the magnetic-field producing means 29. The distribution of plasma density in a space inside the process chamber 21 during the processing on the substrate can be controlled by magnetic fields produced by the magnetic-field producing means 29.

The magnetic-field producing means 29 are preferably provided inside the process chamber 21. The process chamber 21 is formed to be strong enough to withstand being vacuumed inside. If the magnetic-field producing means 29 are provided outside the process chamber 21, the distance between the magnetic-field producing means 29 and the substrate 2 becomes longer. Hence, to improve the plasma density near the substrate 2, a larger magnetic force needs to be generated. For this reason, the magnetic-field producing means 29 are provided inside the process chamber 21 so that permanent magnets having a small magnetic force can be used as the magnetic-field producing means 29. The cost of manufacturing the magnetic-field producing means 29 can thus be reduced.

Although permanent magnets or electromagnets can be used as the magnetic-field producing means 29, the permanent magnets are preferable, being advantageous in terms of cost. The shields 28 are electrically grounded, and function as anode upon plasma production in the process chamber 21. Hence, desirably, the shields 28 are either non-magnetic or weakly magnetic so as not to influence lines of magnetic fields produced by the magnetic-field producing means 29, and are conductive so as to function as anode. For example, aluminum, stainless steel, titanium, or the like is used. Note that, since it is only necessary that the plasma CVD apparatus according to the present invention is configured such that the potential of the shields 28 is higher than that of the substrate 2, a device configuration different from the one in which the shields 28 are grounded can be employed, such as one provided with a power source for making the potential of the shields 28 positive.

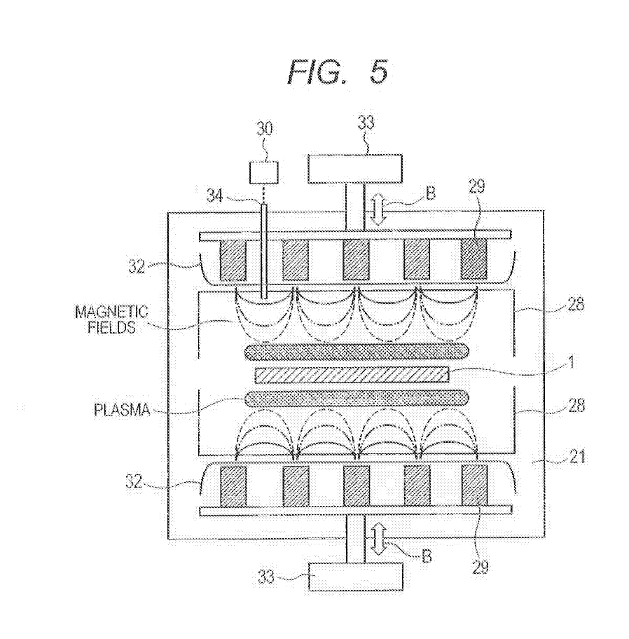

FIG. 5 shows the process chamber 21 in an enlarged manner. In FIG. 5, the magnetic-field producing means 29 are each provided with moving means 33 which allows adjustment of a distance between the magnetic-field producing means 29 and the substrate 2.

The moving means 33 moves the magnetic-field producing means 29 in a direction B in which the volume of a space between the magnetic-field producing means 29 and the holder 1 or the substrate 2 increases or decreases (e.g., a direction in which the distance between the magnetic-field producing means 29 and the substrate 2 changes or a direction normal to the substrate 2). Since the direction only has to be one in which the volume of a space between the magnetic-field producing means 29 and the hold 1 or the substrate 2 increases or decreases, the magnetic-field producing means 29 may be moved in a direction shifted from the direction normal to the substrate 2 by a certain angle. This changes the strength of the magnetic fields near the substrate 2, and can therefore change the plasma density near the substrate 2.

By thus changing the plasma density near the substrate, current flowing from the plasma to the substrate 2 changes, which allows a film formation speed or a substrate temperature to be changed without changing other conditions such as voltage.

The distance between each shield 28 and the substrate 2 is maintained to be about 50 mm to 100 mm. The distance between each shield 28 and the magnetic-field producing means can be changed by the moving means 33 between 10 mm and 50 mm, inclusive.

The moving means 33 of this embodiment can be connected to, for example, a controller including a general computer and various drivers. Specifically, the controller may include a CPU configured to execute processing operations such as various computations, controls, and determinations and a ROM configured to store various control programs executed by the CPU. The controller may include: a RAM configured to temporarily store data used during the processing operation of the CPU, input data, and the like; a nonvolatile memory such as a flash memory or an SRAM; and the like. With such a configuration, the controller may control the moving means 33 according to predetermined programs stored in the ROM or instructions from a higher-level device and based on a value obtained by the temperature measuring means 30, to move the magnetic-field producing means 29 accordingly.

Specifically, upon processing of the substrate 2, the temperatures of the substrate 2 is measured by the temperature measuring means 30 through the port 34. If the temperature is lower than a predetermined temperature, the moving means 33 decreases the distance between the magnetic-field producing means 29 and the substrate 2. Thereby, the plasma density near the substrate 2 is increased to raise the temperature of the substrate 2 so that the temperature of the substrate 2 may approximate to the predetermined temperature. In contrast, if the temperature of the substrate 2 is higher than the predetermined temperature, the moving means 33 increases the distance between the magnetic-field producing means 29 and the substrate 2. Thereby, the plasma density near the substrate 2 is decreased to lower the temperature of the substrate 2 so that the temperature of the substrate 2 may approximate to the predetermined temperature.

A heat dissipating sheet 32 is provided between the magnetic-field producing means 29 and the shield 28. The shield 28 is heated by the plasma produced in the process chamber 21, and the heat dissipating sheet 32 prevents the magnetic-field producing means 29 from receiving the heat of the shield 28. A material having high thermal conductivity, such as aluminum, is used as the heat dissipating sheet 32. Note that the heat dissipating sheet 32 is desirably a non-magnetic material so as not to influence the lines of magnetic fields produced by the magnetic-field producing means 29.

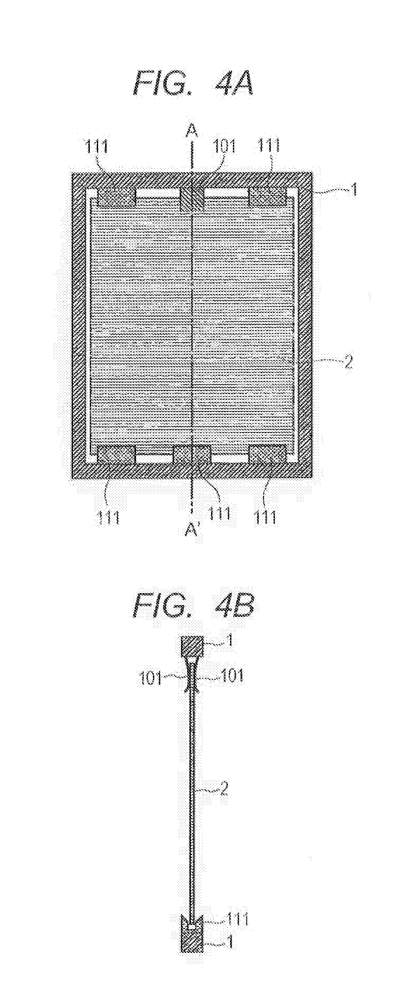

FIG. 4A shows a front view of the holder 1 holding the substrate 2. FIG. 4B shows a sectional view taken along A-A′ line in FIG. 4A. Note that FIGS. 4A and 4B do not show the slider 3.

The substrate 2 used in this embodiment is a metal sheet member having a thickness of about 0.1 mm formed into a quadrangles of about 50×50 mm to 500×500 mm. The holder 1 includes spring support portions 101 which sandwich the substrate 2 to enable the substrate 2 to be held by a conductive holder body having a quadrangle frame shape. The holder 1 also includes guide portions 111 for preventing shaking of the substrate 2 upon its transport and preventing deformation, such as warpage, of the substrate 2 due to thermal expansion or the like. Metal plates are used for the spring support portions 101 to apply high voltage to the substrate 2 through them. For the guide portions 111, an insulating material having low thermal conductivity is used to suppress escape of heat. Further, the spring support portions 101 each have such a shape that its tip end portion extends outward so as to facilitate insertion of the substrate 2.

In this embodiment, as shown in FIGS. 4A and 4B, the spring support portions 101 are provided at a single place on an upper center portion of the substrate 2, and hold the substrate. Being members for preventing flexure of the substrate 2, the guide portions 111 do not need to be in contact with the substrate 2.

The sheet substrate 2 is held by the holder 1 which is a substrate holder supported by the slider 3. Thus, while being held vertically, the substrate 2 is processed on its both surfaces. Since high voltage is applied to the substrate 2 via the spring support portions 101 of the holder 1, the potential of the holder 1 and that of the substrate 2 become substantially equal.

The holder 1 transported from the load lock chamber 11 is stopped at a predetermined position (processing position) in the process chamber 21, and the gate valve 31 is closed to isolate the process chamber 21 from other processing chambers.

The holder 1 shown in FIGS. 4A and 4B is used as follows. Specificially, the holder 1 is, while holding the substrate 2, transported by the slider 3 between the load lock chamber 11 and the process chamber 21, and the substrate 2 is processed while being held by the holder 1 in the process chamber 21.

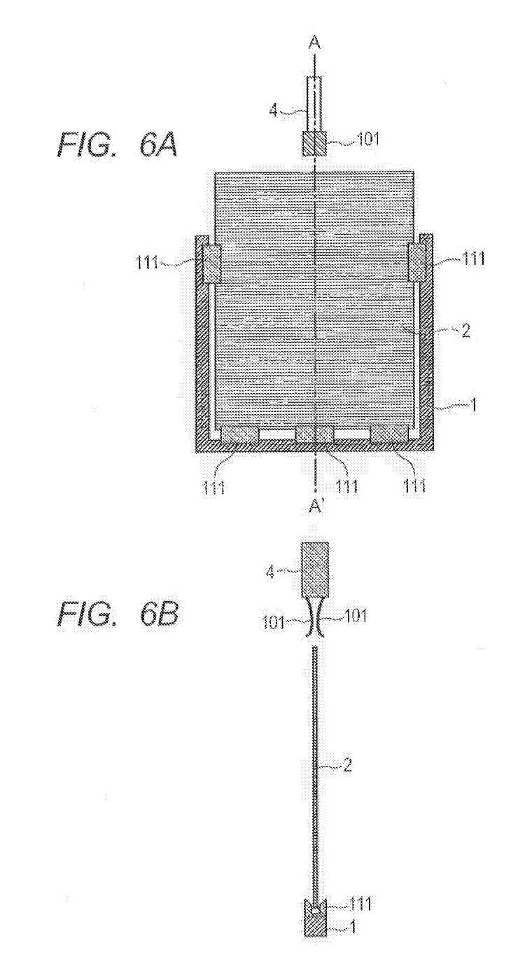

As a modification of the holder 1, FIG. 6A shows a front view of the holder 1 holding the substrate 2, and FIG. 6B shows a sectional view taken along A-A′ in FIG. 6A. The holder 1 shown in FIGS. 6A and 6B is similar to that shown in FIGS. 4A and 4B, but is different therefrom in that one of the edges of the holder 1 is cut away so that the substrate 2 can be slid and removed therethrough. Further, a conductive substrate support portion 4 is provided inside the process chamber 21, and the spring support portions 101 are provided not onto the holder 1, but onto the substrate support portion 4. The voltage application part X is connected to the substrate support portion 4, and voltage is applied to the substrate 2 via the substrate support portion 4 and the spring support portions 101.

With such a configuration, the holder 1 holding the substrate 2 is transported by the slider 3 into the process chamber 21, and the substrate 2 is removed from the holder 1 and held by the spring support portions 101. Then, only the holder 1 is returned from the process chamber 21 to the load lock chamber 11. Thus, film deposition onto the holder 1 during film formation can be prevented.

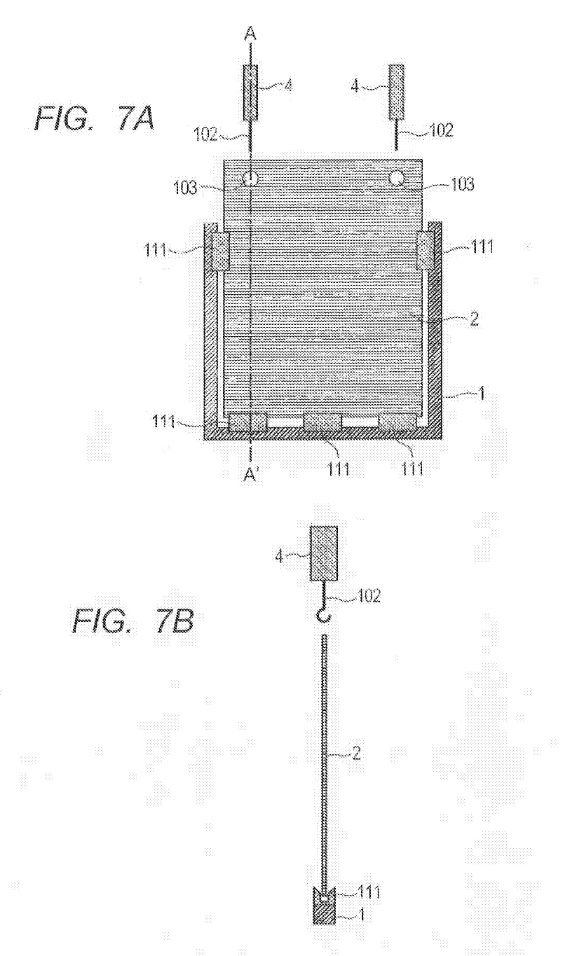

As another modification of the holder 1, FIG. 7A shows a front view of the holder 1 holding the substrate 2, and FIG. 7B shows a sectional view taken along A-A′ in FIG. 7A. The holder 1 shown in FIGS. 7A and 7B is similar to that shown in FIGS. 4A and 4B, but is different therefrom in that one of the edges of the holder 1 is cut away so that the substrate 2 can be slid and removed therethrough. Further, conductive substrate support portions 4 are provided inside the process chamber 21, and a conductive hook 102 for suspending the substrate 2 is provided onto each substrate support portion 4. A substrate provided with hook openings 103 through which the respective hooks 102 can be inserted is used as the substrate 2. The voltage application part X is connected to the substrate support portions 4, and voltage is applied to the substrate 2 via the substrate support portions 4 and the hooks 102.

With such a configuration, the holder 1 holding the substrate 2 is transported by the slider 3 into the process chamber 21, and the substrate 2 is removed from the holder 1 and held by the hooks 102. Then, only the holder 1 is returned from the process chamber 21 to the load lock chamber 11. Thus, film deposition onto the holder 1 during film formation can be prevented.

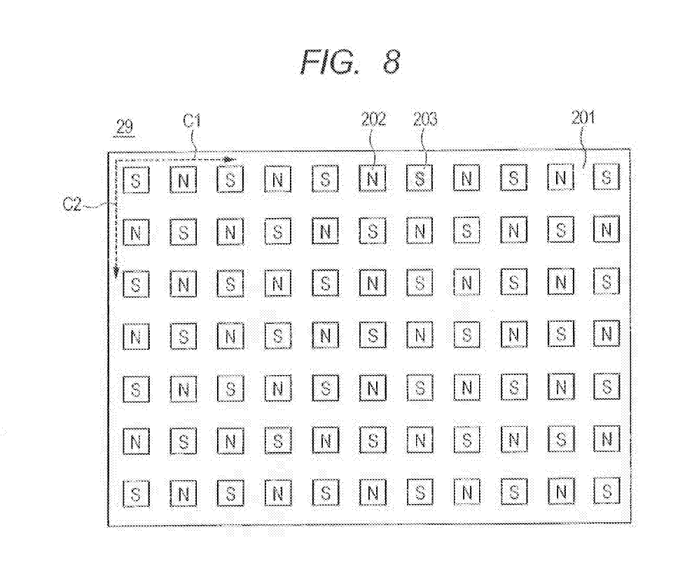

In this embodiment, permanent magnets are used as the magnetic-field producing means 29. The configuration of the permanent magnets is not particularly limited as long as they can produce magnetic fields to confine plasma near the substrate. FIGS. 8, 9, and 10 schematically show examples of the magnetic-field producing means 29 seen from the substrate 2 side.

The magnetic-field producing means 29 shown in FIG. 8 is formed by a group of small permanent magnets provided on a magnet holding surface 201 facing the substrate 2. This group of small permanent magnets includes magnets 202 whose magnetic pole on the substrate side is a north pole and magnets 203 whose magnetic pole on the substrate side is a south pole. In the group of permanent magnets, the permanent magnets adjacent in a first direction C1 on the magnetic holding surface 201 have opposite magnetic poles on the substrate side to each other, and the permanent magnets adjacent in a second direction C2 perpendicular to the first direction C1 on the magnetic holding surface 201 have opposite magnetic poles on the substrate side to each other. Further, a certain permanent magnet and a permanent magnet adjacent to both of a permanent magnet adjacent to the certain permanent magnet in the first direction C1 and a permanent magnet adjacent to the certain permanent magnet in the second direction C2 (i.e., permanent magnets located diagonally to each other in a square formed by four permanent magnets) have the same magnetic pole on the substrate side.

In this way, when the magnetic-field producing means 29 is formed by multiple small permanent magnets, many horizontal magnetic fields are formed on the substrate side. For this reason, a plasma can be confined near the substrate evenly in an in-plane direction of the substrate. Thereby, film formation having favorable in-plane distribution can be accomplished without depending on the shape or size of the substrate.

The magnetic holding surface 201 may be provided with yokes on which the magnets 202 and 203 are to be provided. According to such a configuration, the heat resistance of the magnets can be improved, and even if the temperatures of the magnets are increased by the plasma, the strength of the magnetic fields in the process chamber 21 can be prevented from decreasing.

As shown in FIG. 9, the magnetic-field producing means 29 may be formed by a group of annular permanent magnets provided coaxially on a magnet holding surface 211 facing the substrate 2. The group of annular permanent magnets includes annular magnets 212 whose magnetic pole on the substrate side is a north pole and annular magnets 213 whose magnetic pole on the substrate side is a south pole. The magnets 212 and the magnets 213 having different magnetic poles on the substrate side are arranged alternately on the magnet holding surface 211.

When the magnetic-field producing means 29 is thus formed of annular magnets, horizontal magnetic fields formed on the substrate side are larger than those formed by other configurations. For this reason, this configuration is advantageous when large magnetic fields are to be formed in a plasma produced space.

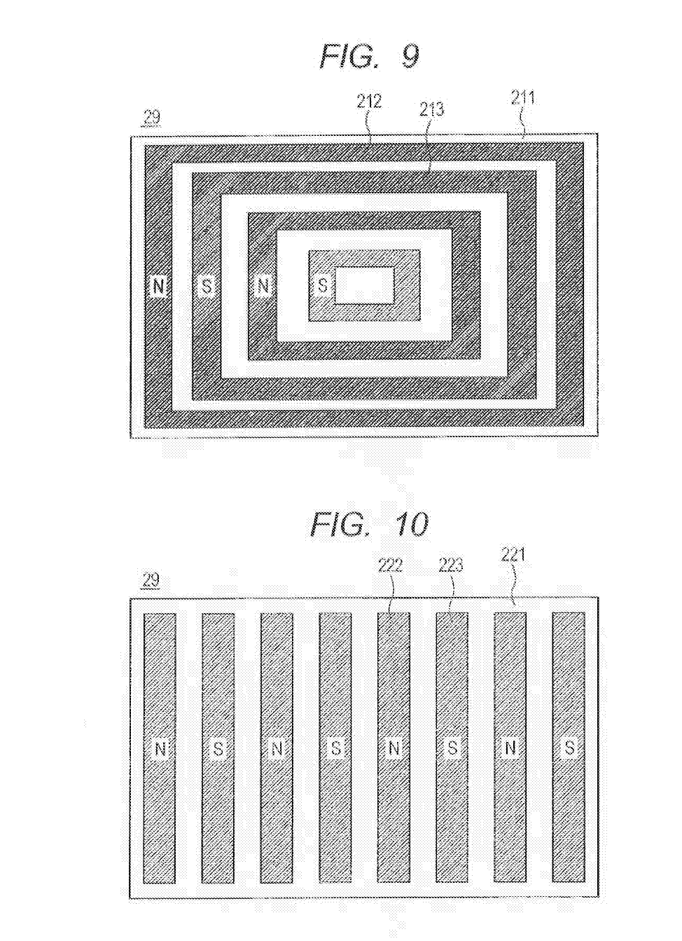

As shown in FIG. 10, the magnetic-field producing means 29 may be formed by a group of bar permanent magnets provided side by side on a magnetic holding surface 221 facing the substrate 2. The group of bar permanent magnets includes bar magnets 222 whose magnetic pole on the substrate side is a north pole and bar magnets 223 whose magnetic pole on the substrate side is a south pole. The magnets 212 and the magnets 213 having different magnetic poles on the substrate side are arranged alternately on the magnet holding surface 221.

When the magnetic-field producing means 29 is thus formed of bar magnets, the area of the horizontal magnetic fields can be changed easily by adding a bar magnet. Hence, this configuration can easily be applied to cases such as where film formation is performed under the bar magnets while moving the substrate 2.

In this embodiment, the magnetic-field producing means 29 are provided inside the process chamber 21. This is advantageous in that the distribution of plasma density can be changed even with permanent magnets producing a weak magnetic field. In another mode, the magnetic-field producing means 29 may be provided outside the process chamber 21. Although this mode is advantageous in that film deposition on the magnetic-field producing means 29 can be prevented and that heating of the magnetic-field producing means 29 can be reduced, permanent magnets capable of producing a stronger magnetic field need to be used.

Next, a description is given of a film formation process performed on the substrate 2 in the process chamber 21.

In this embodiment, a DLC film is formed on the substrate 2. It is desirable that the DLC film formation on the substrate 2 be performed with the substrate 2 being heated. Hence, a heating process is performed on the substrate 2 prior to the film formation. First, an inert gas is introduced into the process chamber 21. Next, the voltage application cylinder 23 is driven to bring the holder 1 and the voltage application part X into electrical contact with each other.

Negative high voltage which is applied by the voltage application part X is direct-current (DC) voltage or high-frequency alternating-current voltage, and application of the high voltage to the substrate 2 produces a plasma in a region in the process chamber 21, the region including at least a space between magnetic-field producing means 29 and the substrate 2. For the plasma production, direct-current voltage is preferable, being advantageous in that the apparatus can be manufactured less expensively than a conventional apparatus.

With the plasma being produced in the process chamber 21, the moving means 33 each make the distance between the corresponding magnetic-field producing means 29 and the substrate 2 approximate to a first distance to thereby increase the plasma density near the substrate 2 and increase current flowing to the substrate. Thus, the substrate 2 is speedily heated up to a desired temperature. In other words, according to this embodiment, the temperature of the substrate 2 can be adjusted as a result of adjusting the distance between each magnetic-field producing means 29 and the substrate 2 or the holder 1 holding the substrate 2 to thereby change the amount of current flowing to the substrate without changing voltage applied.

After the substrate 2 is heated, to perform a film formation process, a hydrocarbon gas is introduced into the process chamber 21. The hydrocarbon gas is decomposed by the plasma produced inside the process chamber 21, and ions are attracted to the substrate 2 due to the negative voltage applied to the substrate 2. Thus, a carbon film is formed on the substrate. The film formation process can be performed while controlling the temperature of the substrate 2 to a desired temperature by the moving means 33 adjusting the distance between the magnetic-field producing means 29 and the substrate 2 to a second distance which is different from the first distance. For example, since the temperature does not need to be increased rapidly in the film formation process unlike the heating process, the distance between the magnetic-field producing means 29 and the substrate 2 in the film formation process is longer than that in the heating process, i.e., the second distance is longer than the first distance.

In this embodiment, a plasma is produced near the substrate 2 by the application of voltage to the holder 1 and the substrate 2, and is confined near the substrate 2 by the magnetic fields produced by the magnetic-field producing means 29. Thus, speedy heating of the substrate 2 and suppression of film attachment to portions other than the substrate 2 can be accomplished. Further, the film formation can be performed speedily.

In another method, a plasma may be produced by applying voltage to electrodes provided outside the holder 1, e.g., between the holder 1 and the shields 28. Also in this case, the electrodes are desirably located near the substrate. Thereby, a plasma can be produced near the substrate 2 and can be confined by the magnetic fields.

In the example described in the above embodiment, in the substrate processing procedure, the distance between the substrate and the magnets is made different in the heating step and in the film forming step. Besides this example, in the present invention, making the distance between the substrate and the magnets different at the initial stage and at the terminal stage of the film forming step, for example, enables such controls as making the substrate temperature or the film properties (e.g., film stress) different at the initial stage and at the terminal stage of the film forming step.

### EXAMPLE

An example is shown below of forming DLC films on the substrate 2 by using the plasma CVD apparatus shown in FIG. 1. Note that the magnetic-field producing means 29 used here were the one shown in FIG. 8.

First, the substrate 2 was transported to the process chamber 21, and the gate valve 31 was closed. Then, as an inert gas, an Ar gas was introduced from the gas introduction portion 24 at 500 sccm (standard cc/min). By this introduction of the Ar gas, the internal pressure of the process chamber 21 was brought to 20 Pa.

With magnetic fields being produced inside the process chamber 21 by permanent magnets used as the magnetic-field producing means 29, a pulse voltage of minus 400 V was applied by the voltage application part X to produce a plasma. The distance between the substrate 2 and each shield 28 at this time was 60 mm, and the distance between the shield 28 and the magnetic-field producing means 29 was set to 10 mm by the moving means 33. Under this state, the substrate 2 was heated by the plasma for about five seconds to reach a temperature of about 500° C.

By thus performing the heating process of the substrate by the plasma of the Ar gas before forming the DLC films, the surface of the substrate is cleaned, and adsorbed gas is removed. Thereby, DLC films of desired film quality are obtained, and also, the adhesiveness between the substrate and the DLC films improve.

Next, as a source gas, an ethylene gas was introduced into the process chamber 21 at 250 sccm to bring the pressure of the process chamber 21 to 20 Pa. Further, the distance between each shield 28 and the magnetic-field producing means 29 was changed to 30 mm by the moving means 33. Then, a pulse voltage of minus 1000 V was applied to the substrate 2 to produce a plasma. By keeping applying the voltage for about 100 seconds, DLC films each having a thickness of about 100 nm were formed.

Note that the embodiment of the present invention described above can be modified variously without departing from the gist of the invention.

1. A CVD method for performing a film forming process on a substrate by using a film forming apparatus including a vacuum vessel and magnetic-field producing means for generating a magnetic field inside the vacuum vessel, characterized in that the method comprises the steps of:
producing a plasma in a space between the magnetic-field producing means and the substrate inside the vacuum vessel; and
while the substrate is being processed, moving the magnetic-field producing means in such a direction as to increase or decrease a volume of the space between the magnetic-field producing means and the substrate.

2. The CVD method according to claim 1, characterized in that
the magnetic-field producing means is provided inside the vacuum vessel.

3. The CVD method according to claim 1, characterized in that
in the moving step, the magnetic-field producing means is moved in a direction normal to the substrate.

4. The CVD method according to claim 1, characterized in that
the plasma is produced by a gas containing hydrocarbon, and
a carbon film is formed on the substrate by the plasma of the gas containing hydrocarbon.

5. A CVD method for performing a film forming process on a substrate by using a film forming apparatus including a vacuum vessel and magnetic-field producing means for generating a magnetic field inside the vacuum vessel, characterized in that the method comprises the steps of:
moving the magnetic-field producing means so that a distance between the magnetic-field producing means and the substrate reaches a first distance;
producing a plasma of an inert gas in a space between the magnetic-field producing means and the substrate inside the vacuum vessel;
heating the substrate by the plasma of the inert gas;
moving the magnetic-field producing means so that the distance between the magnetic-field producing means and the substrate reaches a second distance which is larger than the first distance;
producing a plasma of a source gas in the space between the magnetic-field producing means and the substrate inside the vacuum vessel; and
forming a film on the substrate by the plasma of the source gas.

6. The CVD method according to claim 5, characterized in that
the magnetic-field producing means is provided inside the vacuum vessel.

7. The CVD method according to claim 5, characterized in that
in the moving steps, the magnetic-field producing means is moved in a direction normal to the substrate.

8. The CVD method according to claim 5, characterized in that
the source gas is a gas containing hydrocarbon, and
a carbon film is formed on the substrate by the plasma of the gas containing hydrocarbon.
